(19) United States
(12) Patent Application Publication
(10) Pub. No.: US 2025/0291343 A1
(43) Pub. Date: Sep. 18, 2025

(54) INFORMATION PROCESSING APPARATUS, SUBSTRATE PROCESSING APPARATUS, AND INFORMATION PROCESSING METHOD

(71) Applicant: Tokyo Electron Limited, Tokyo (JP)

(72) Inventors: Shingo NISHIMOTO, Yamanashi (JP); Tatsuya YAMAGUCHI, Yamanashi (JP); Ryosuke SHIBATSUJI, Iwate (JP); Yuichi TAKENAGA, Yamanashi (JP)

(21) Appl. No.: 19/072,450

(22) Filed: Mar. 6, 2025

(30) Foreign Application Priority Data
Mar. 12, 2024 (JP) 2024-037854

(51) Int. Cl. G05B 23/02; H01L 21/67

(52) U.S. Cl. CPC G05B 23/0221; H01L 21/67248; G05B 2219/2602

(57) ABSTRACT

An information processing apparatus includes an acquisition unit that acquires measurement data including a first physical quantity indicating a state within a processing container for processing a processing target and a second physical quantity indicating a state of the processing target, a determination unit that determines a parameter of a model representing a relationship between the first physical quantity and the second physical quantity, based on the measurement data, and an optimization unit that optimizes a set value of the first physical quantity to minimize a time required for the second physical quantity to satisfy a target value, based on the model with the parameter determined by the determination circuitry set therein.

### CROSS-REFERENCE TO RELATED APPLICATIONS

This application is based on and claims priority from Japanese Patent Application No. 2024-037854 filed on Mar. 12, 2024, with the Japan Patent Office, the disclosure of which is incorporated herein its entirety by reference.

### TECHNICAL FIELD

The present disclosure relates to an information processing apparatus, a substrate processing apparatus, and an information processing method.

### BACKGROUND

A substrate processing apparatus capable of measuring the temperature of a processing target has been known. For example, International Patent Application Publication No. 2020/059722 discloses a substrate processing apparatus including a substrate holder that is inserted into a processing chamber while having a substrate disposed thereon, a rotating mechanism that rotates the substrate holder, and a substrate temperature sensor that rotates simultaneously with the substrate when the substrate holder is rotated and measures the temperature of the substrate.

### SUMMARY

According to one aspect of the present disclosure, an information processing apparatus includes: an acquisition unit configured to acquire measurement data including a first physical quantity indicating a state within a processing container for processing a processing target and a second physical quantity indicating a state of the processing target; a determination unit configured to determine a parameter of a model representing a relationship between the first physical quantity and the second physical quantity, based on the measurement data; and an optimization unit configured to optimize a set value of the first physical quantity to minimize a time required for the second physical quantity to satisfy a target value, based on the model with the parameter determined by the determination unit set therein.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating a response difference between the furnace temperature and the wafer surface temperature.

FIG. 2 is a block diagram illustrating an overall configuration of a substrate processing system according to an embodiment of the present disclosure.

FIG. 3 is a schematic cross-sectional view illustrating a substrate processing apparatus according to the embodiment of the present disclosure.

FIG. 4 is a block diagram illustrating a hardware configuration of a computer according to the embodiment of the present disclosure.

FIG. 5 is a block diagram illustrating a functional configuration of an optimization device according to the embodiment of the present disclosure.

FIG. 6 is a diagram illustrating an example of a temperature sensor.

FIG. 7 is a diagram illustrating an example of optimization calculation.

FIG. 8 is a diagram illustrating an example of model predictive control (MPC).

FIG. 9 is a flowchart illustrating an example of an optimization method according to an embodiment of the present disclosure.

FIG. 10 illustrates an example of an optimization result.

FIG. 11 illustrates an example of an evaluation result at the time of temperature increase.

FIG. 12 illustrates an example of an evaluation result at the time of temperature decrease.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented herein.

Hereinafter, embodiments of the present disclosure will be described with reference to the drawings. In the respective drawings, the same components may be denoted by the same reference numerals, and overlapping descriptions thereof may be omitted.

### Embodiment

An embodiment of the present disclosure relates to a substrate processing system including a substrate processing apparatus that processes a substrate, which is an example of a processing target. In the present embodiment, the substrate processing apparatus heat-treats a semiconductor wafer, which is an example of a substrate, within a processing container. The substrate processing system includes an optimization device that optimizes a temperature within the processing container (hereinafter, also referred to as “furnace temperature”), which is an example of a physical quantity.

In a substrate processing apparatus that heat-treats a semiconductor wafer, the surface temperature of the semiconductor wafer (hereinafter, also referred to as “wafer surface temperature”) affects the accuracy of a process result. However, in the substrate processing apparatus, it is difficult to directly measure the wafer surface temperature from the semiconductor wafer which is being processed. Therefore, the wafer surface temperature is indirectly controlled by controlling the furnace temperature.

There is a difference in the responsiveness between the furnace temperature and the wafer surface temperature. For example, even when the furnace temperature is increased or decreased to a target temperature, it is required to take a certain amount of time until the wafer surface temperature is stabilized to the target temperature. For example, in a process performed at a low temperature, a response difference tends to increase since the emissivity of silicon, which is a raw material for the semiconductor wafer, decreases. For example, at a low temperature of 50° C. to 60° C., there is a response difference of 60 minutes or more until the wafer surface temperature is stabilized.

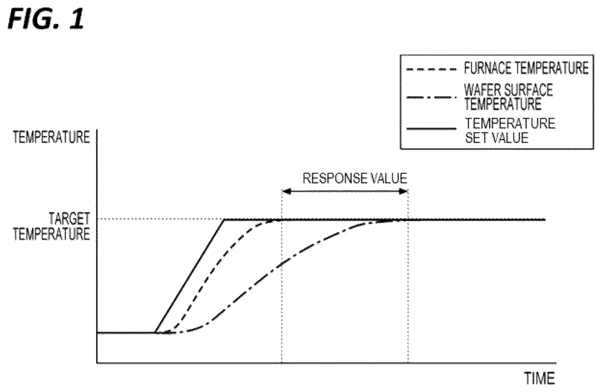

FIG. 1 is a diagram illustrating a response difference between the furnace temperature and the wafer surface temperature. In FIG. 1, the solid line is a set value of the furnace temperature (hereinafter, referred to as a “temperature set value”), the dashed line is an actually measured value of the furnace temperature, and the dash-dotted line is the wafer surface temperature. As illustrated in FIG. 1, when the temperature set value is increased, the furnace temperature increases first. Meanwhile, the wafer surface temperature starts to increase later after the furnace temperature starts to increase. There is a certain time difference between the time when the furnace temperature is stabilized to the target temperature and the time when the wafer surface temperature is stabilized to the target temperature. The time difference is the response difference.

In order to stabilize the wafer surface temperature in a short period of time, temperature control may be performed by overshooting the furnace temperature. However, since it is difficult to measure the wafer surface temperature, it is also difficult to appropriately determine an overshoot amount. The term “overshoot” means a temperature control that temporarily increases (or decreases) the temperature to be higher (or lower) than a target temperature.

There has been known a technique for predicting the wafer surface temperature, instead of measuring the wafer surface temperature. However, since there is a limit to the prediction accuracy of the wafer surface temperature, it is necessary to improve the prediction accuracy. For example, there are some cases where a gap between the wafer surface temperature and a predicted value increases due to the influence of a change in a state within the processing container.

In addition, a technique for measuring the temperature in the vicinity of a semiconductor wafer (hereinafter, also referred to as “wafer vicinity temperature”), instead of the wafer surface temperature, has been proposed. As an example, a substrate processing apparatus has been known, in which a temperature sensor is installed in a substrate holder on which a semiconductor wafer is disposed. However, in order to install the temperature sensor in the substrate holder, a change in the design of the substrate holder or the rotation mechanism of the substrate processing apparatus is required, thereby resulting in a significant increase in a manufacturing cost of the substrate processing apparatus.

In the present embodiment, it is intended to control the wafer surface temperature with high accuracy. Therefore, in the present embodiment, the set value of the furnace temperature is optimized to minimize the time required for the wafer surface temperature to be stabilized to the target temperature (hereinafter, also referred to as the “stabilization time”), based on a model representing the relationship between the furnace temperature and the wafer surface temperature.

In one aspect, according to the present embodiment, the wafer surface temperature may be controlled with high accuracy based on the optimized set value of the furnace temperature. Therefore, according to the present embodiment, since the wafer surface temperature is stabilized to the target temperature in a short period of time, the substrate may be efficiently processed, thereby improving productivity. In another aspect, according to the present embodiment, since it is unnecessary to change a hardware design of the substrate processing apparatus, the cost required to improve the accuracy of temperature control may be reduced.

### <System Configuration>

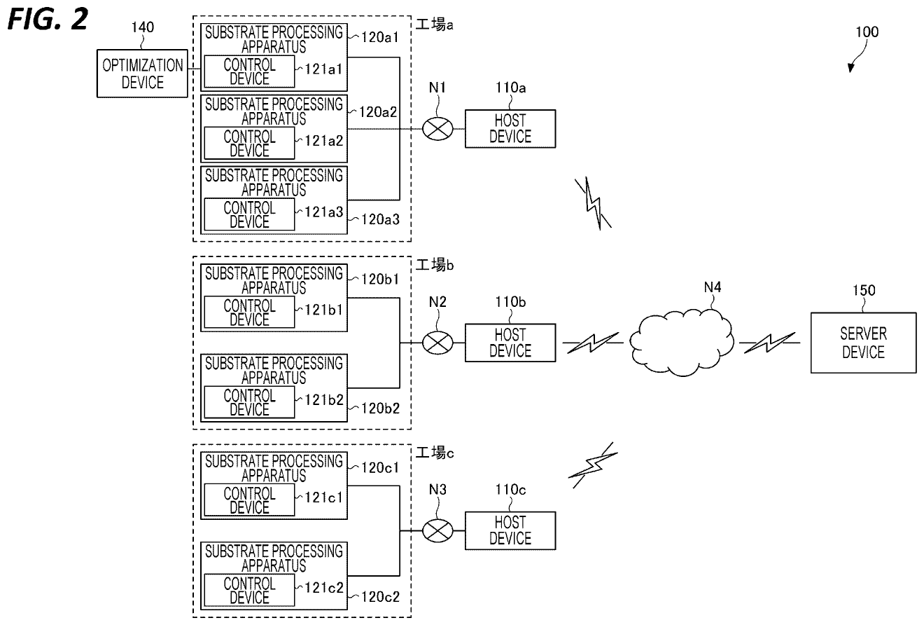

An overall configuration of the substrate processing system in the present embodiment will be described with reference to FIG. 2. FIG. 2 is a block diagram illustrating the overall configuration of the substrate processing system according to the embodiment of the present disclosure.

As illustrated in FIG. 2, a substrate processing system 100 includes substrate processing apparatuses 120al to 120a3 and control devices 121al to 121a3 in a factory a. The substrate processing apparatuses 120a1 to 120a3 and the control devices 121al to 121a3 are connected in a wired or wireless manner.

In addition, the substrate processing system 100 includes substrate processing apparatuses 120b1 and 120b2 and control devices 121b1 and 121b2 in a factory b. The substrate processing apparatuses 120b1 and 120b2 and the control devices 121b1 and 121b2 are connected in a wired or wireless manner.

Furthermore, the substrate processing system 100 includes substrate processing apparatuses 120c1 and 120c2 and control devices 121c1 and 121c2 in a factory c. The substrate processing apparatuses 120c1 and 120c2 and the control devices 121cl and 121c2 are connected in a wired or wireless manner.

The substrate processing apparatuses 120a1 to 120a3, the substrate processing apparatuses 120b1 and 120b2, and the substrate processing apparatuses 121c1 and 121c2 are connected to host devices 110a, 110b, and 110c, respectively, via networks N1 to N3. Under the control of each control device based on instructions from the host devices 110a, 110b, and 110c, each substrate processing apparatus performs a substrate processing. The host devices 110a, 110b, and 110c are connected to a server device 150 via a network N4, such as the Internet.

In the following description, the substrate processing apparatuses 120al to 120a3, 120b1, 120b2, 120c1, and 120c2 are also collectively referred to as a substrate processing apparatus 120. The control devices 121a1 to 121a3, 121b1, 121b2, 121c1, and 121c2 are also collectively referred to as a control device 121. The host devices 110a, 110b, and 110c are also collectively referred to as a host device 110.

The substrate processing apparatuses 120a1 to 120a3, the substrate processing apparatuses 120b1 and 120b2, and the substrate processing apparatuses 120c1 and 120c2 store in their own apparatuses a wide range of data that they each manage.

An optimization device 140 is connected to the substrate processing apparatus 120 including the substrate processing apparatus 120a1, and continuously acquires data accumulated in each substrate processing apparatus 120. The example of FIG. 2 illustrates a state where the optimization device 140 is connected to the substrate processing apparatus 120a1, but the present disclosure is not limited thereto. Hereinafter, a case where the optimization device 140 is connected to the substrate processing apparatus 120al will be described in detail in the present embodiment.

The substrate processing system 100 illustrated in FIG. 2 is provided by way of example, and examples of various system configurations may be provided depending on usage or purposes. The classification of apparatuses such as the host device 110, the substrate processing apparatus 120, the control device 121, the optimization device 140, and the server device 150 illustrated in FIG. 2 is provided by way of example. For example, the number of factories, the number of host devices 110, the number of substrate processing apparatuses 120, the number of control devices 121, and the number of optimization devices 140 are provided by way of example and are not limited thereto.

For example, the substrate processing system 100 may have various configurations such as a configuration in which at least two of the host device 110, the substrate processing apparatus 120, the control device 121, the optimization device 140, and the server device 150 are integrated or they are further separated. For example, the control device 121 may control a plurality of substrate processing apparatuses 120 in an integrated manner, or a single control device may be provided for each substrate processing apparatus 120 or may be integrated with the substrate processing apparatus 120.

The optimization device 140 may be implemented by the host device 110, or may be implemented by the server device 150. In this case, the optimization device 140 is unnecessary. In addition, the optimization device 140 may be implemented by the control device 121. The optimization device 140 may be implemented by a control device (not illustrated) that controls a plurality of control devices 121 in an integrated manner.

### <Substrate Processing Apparatus>

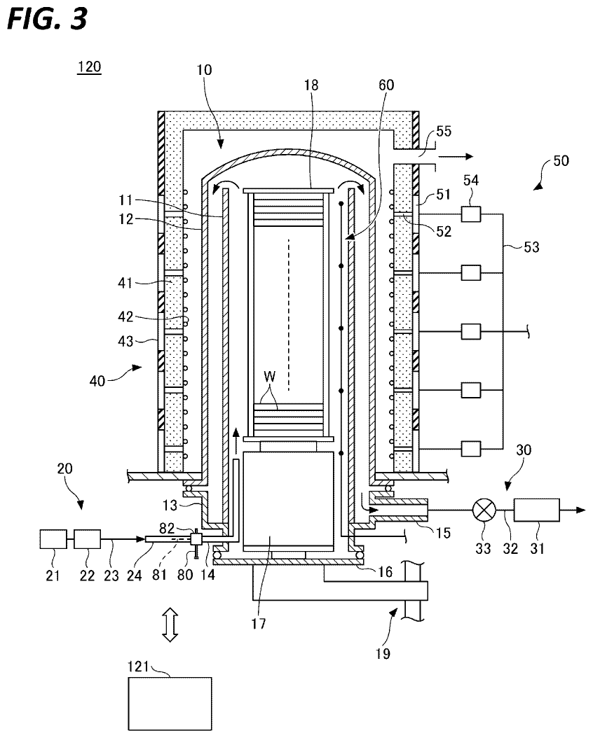

An example of a substrate processing apparatus in the present embodiment will be described with reference to FIG. 3. FIG. 3 is a schematic cross-sectional view illustrating a vertical-type heat treatment apparatus, which is an example of the substrate processing apparatus in the present embodiment.

A vertical-type heat treatment apparatus 120 in the present embodiment is a substrate processing apparatus that accommodates a plurality of semiconductor wafers W, which are an example of processing targets, at once and performs heat treatment thereon, such as oxidation, diffusion, or low-pressure chemical vapor deposition (CVD). As illustrated in FIG. 2, the vertical-type heat treatment apparatus 120 includes a processing container 10, a gas supply unit 20, an exhaust port 30, a heating unit 40, a cooling unit 50, and the control device 121.

The processing container 10 has an approximately cylindrical shape. The processing container 10 includes an inner tube 11, an outer tube 12, a manifold 13, an injector 14, a gas outlet 15, and a cover 16. The inner tube 11 has an approximately cylindrical shape. The outer tube 12 has an approximately cylindrical shape with a ceiling and forms a double-tube structure by the inner tube 11 and the outer tube 12. The inner tube 11 and the outer tube 12 are formed of a heat-resistant material, such as quartz, for example.

The manifold 13 has an approximately cylindrical shape. The manifold 13 supports lower ends of the inner tube 11 and the outer tube 12. The manifold 13 is formed of, for example, stainless steel. The injector 14 penetrates the manifold 13 and extends horizontally within the inner tube 11, and bends in an L-shape and extends upwardly within the inner tube 11. The injector 14 has a base end connected to a gas introduction pipe 24 and an open front end. The injector 14 ejects a processing gas (hereinafter, simply referred to as “gas”) introduced through the gas introduction pipe 24 into the inner tube 11 from an opening at the front end. One or more injectors 14 may be provided.

The gas outlet 15 is formed in the manifold 13. The processing gas is exhausted by the exhaust port 30 through the gas outlet 15. The cover 16 hermetically seals an opening at a bottom of the manifold 13. The cover 16 is formed of, for example, stainless steel. On the cover 16, a wafer boat (substrate holder) 18 is disposed via a heat insulation tank 17. The heat insulation tank 17 and the wafer boat 18 are formed of a heat-resistant material such as, for example, quartz.

The wafer boat 18 holds a plurality of semiconductor wafers W approximately horizontally with predetermined intervals in a vertical direction. A lifting mechanism 19 raises the cover 16, so that the wafer boat 18 is carried (loaded) into the processing container 10 and accommodated within the processing container 10. The lifting mechanism 19 lowers the cover 16, so that the wafer boat 18 is carried out (unloaded) from the processing container 10.

The gas supply unit 20 includes a gas source 21, an integrated gas system (IGS) 22, an external pipe 23, and the gas introduction pipe 24. The gas source 21 is a source of processing gases and includes, for example, a film formation gas source, a cleaning gas source, and a purge gas source. The IGS 22 is an integrated circuit of gas pipes and includes a group of pipes connected to the film formation gas source, the cleaning gas source, and the purge gas source, respectively. A flow control unit is installed in the IGS 22 to control a flow of a gas through each pipe. The flow control unit includes, for example, a mass flow controller, and an opening/closing valve.

The IGS 22 is connected to the external pipe 23. The external pipe 23 is connected to the gas introduction pipe 24. A heater (not illustrated) is wound around an outer circumference of the external pipe 23 to heat the external pipe 23. The gas introduction pipe 24 is connected to the processing container 10 to introduce a gas into the processing container 10. For example, a flow of the processing gas from the gas source 21 is controlled by the flow control unit within the IGS 22. Subsequently, the processing gas is heated as it flows through the external pipe 23, flows into the gas introduction pipe 24, and then, is supplied from the gas introduction pipe 24 to the processing container 10 via the injector 14. The injector 14 functions as a gas inlet of the processing container 10.

Near the gas inlet of the processing container 10, a joint 82 for a gas pipe connected to the gas introduction pipe 24 is installed. A temperature sensor 80 is configured to penetrate the joint 82. The temperature sensor 80 is configured to measure the temperature of the gas in the gas introduction pipe 24. The temperature sensor 80 transmits the measured temperature to the control device 121. In addition, a second heater 81 is disposed in the gas introduction pipe 24, and the second heater 81 is configured to heat the gas in the gas introduction pipe 24.

The exhaust port 30 includes an exhaust unit 31, an exhaust pipe 32, and a pressure controller 33. The exhaust unit 31 is a vacuum pump, such as a dry pump or a turbomolecular pump. The pressure controller 33 is installed to the exhaust pipe 32 and adjusts conductance of the exhaust pipe 32 to control a pressure within the processing container 10. The pressure controller 33 is, for example, an automatic pressure control valve.

The heating unit 40 includes an insulator 41, a first heater 42, and an outer cover 43. The insulator 41 has an approximately cylindrical shape and is provided around a periphery of the outer tube 12. The insulator 41 is formed of silica and alumina as main components. The first heater 42 is linear and is provided around an inner circumference of the insulator 41 in a spiral or meandering manner. The first heater 42 is divided into a plurality of zones in a height direction of the processing container 10 and configured to perform temperature control therefor. The outer cover 43 is provided to cover an outer circumference of the insulator 41. The outer cover 43 reinforces the insulator 41 while maintaining the shape of the insulator 41. The outer cover 43 is formed of metal, such as stainless steel. In addition, a water-cooling jacket may be installed on an outer circumference of the outer cover 43 to suppress a thermal influence of the heating unit 40 to the outside. The heating unit 40 heats the inside of the processing container 10 with heat generated by the first heater 42.

The cooling unit 50 supplies a cooling fluid to the processing container 10 to cool a semiconductor wafer W in the processing container 10. The cooling fluid may be, for example, the air. The cooling unit 50 supplies the cooling fluid to the processing container 10 when rapidly cooling the semiconductor wafer W, for example, after heat treatment. The cooling unit 50 includes a fluid channel 51, ejection holes 52, a distribution channel 53, a flow regulator 54, and an arrangement port 55.

A plurality of fluid channels 51 are formed in the height direction between the insulator 41 and the outer cover 43. The fluid channels 51 are, for example, channels formed on an outside of the insulator 41 in a circumferential direction thereof. The ejection hole 52 penetrates through the insulator 41 from each fluid channel 51 and ejects the cooling fluid into a space between the outer tube 12 and the insulator 41. The distribution channel 53 is installed outside the outer cover 43 and is configured to distribute and supply the cooling fluid to each fluid channel 51. The flow regulator 54 is installed to the distribution channels 53 and regulates the flow of the cooling fluid supplied to the fluid channel 51.

The arrangement port 55 is provided above a plurality of the ejection holes 52 and discharges the cooling fluid supplied to the space between the outer tube 12 and the insulator 41 to the outside of the processing container 10. The cooling fluid discharged to the outside of the processing container 10 is cooled, for example, by a heat exchanger, and is supplied to the distribution channel 53 again. However, the cooling fluid discharged to the outside of the processing container 10 may be discharged without being reused.

A temperature sensor 60 detects a temperature within the processing container 10. The temperature sensor 60 is provided, for example, within the inner tube 11. However, the temperature sensor 60 may be provided in any location where the temperature within the processing container 10 may be detected, for example, in a space between the inner tube 11 and the outer tube 12. The temperature sensor 60 includes a plurality of temperature measurement portions provided at different positions in the height direction, for example, corresponding to the plurality of zones. The plurality of temperature measurement portions may be, for example, thermocouples, or temperature measurement resistors. The temperature sensor 60 transmits temperatures detected by the plurality of temperature measurement portions to the control device 121.

The control device 121 controls an operation of the vertical-type heat treatment apparatus 120, thereby controlling a semiconductor process performed in the vertical-type heat treatment apparatus 120. The control device 121 may be, for example, a computer.

### <Computer>

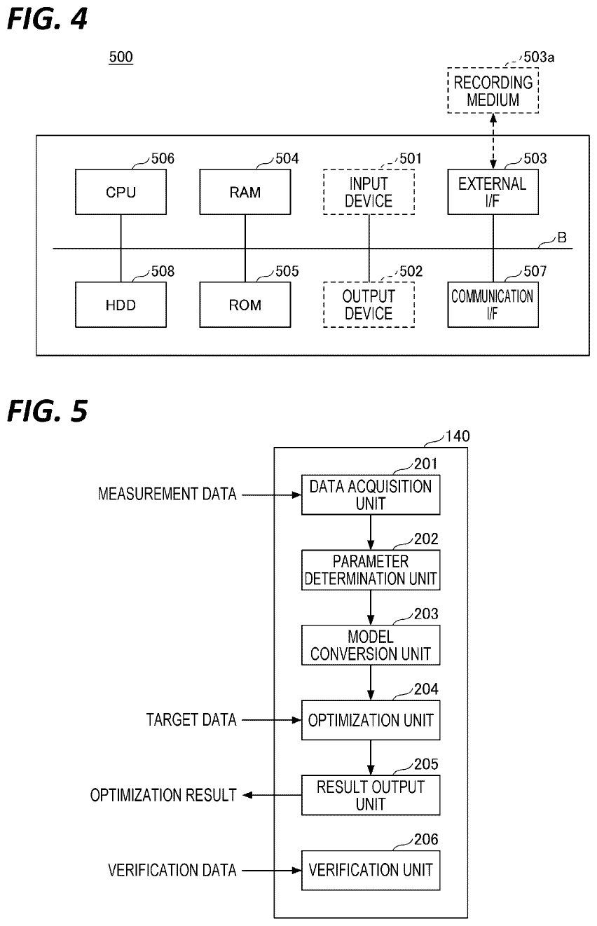

The host device 110, the control device 121, the optimization device 140, and the server device 150 included in the substrate processing system 100 illustrated in FIG. 2 are implemented by a computer with, for example, a hardware configuration, as illustrated in FIG. 4. FIG. 4 is a block diagram illustrating a hardware configuration of a computer in the present embodiment of the present disclosure.

As illustrated in FIG. 4, a computer 500 of the present embodiment includes an input device 501, an output device 502, an external I/F (interface) 503, a random access memory (RAM) 504, a read only memory (ROM) 505, a central processing unit (CPU) 506, a communication I/F 507, and a hard disk drive (HDD) 508, each of which is connected by a bus B. The input device 501 and the output device 502 may be connected and used as needed.

The input device 501 is a keyboard, a mouse, or a touch panel and is used to input each operational signal by an operator. The output device 502 is a display, and displays a result of processing by the computer 500. The communication I/F 507 is an interface that connects the computer 500 to networks. The HDD 508 is an example of a non-volatile storage device that stores programs or data.

The external I/F 503 is an interface to an external device. The computer 500 may perform reading and/or recording on a recording medium 503a, such as a secure digital (SD) memory card, via the external I/F 503. The ROM 505 is an example of a non-volatile semiconductor memory (storage device) in which programs or data are stored. The RAM 504 is an example of a volatile semiconductor memory (storage device) that temporarily holds programs and/or data.

The CPU 506 is a computing device that reads programs or data from the storage device such as the ROM 505 or the HDD 508 and performs a processing to implement control or functions of the entire computer 500.

### <Functional Configuration>

The functional configuration of the optimization device in the present embodiment will be described with reference to FIG. 5. FIG. 5 is a block diagram illustrating the functional configuration of the optimization device in the present embodiment.

As illustrated in FIG. 5, the optimization device 140 includes a data acquisition unit 201, a parameter determination unit 202, a model conversion unit 203, an optimization unit 204, a result output unit 205, and a verification unit 206. The optimization device 140 functions as the data acquisition unit 201, the parameter determination unit 202, the model conversion unit 203, the optimization unit 204, the result output unit 205, and the verification unit 206 by executing a pre-installed optimization program.

The data acquisition unit 201, the parameter determination unit 202, the model conversion unit 203, the optimization unit 204, the result output unit 205, and the verification unit 206 are implemented by, for example, the CPU 506 illustrated in FIG. 4 executing a program loaded on the RAM 504.

The data acquisition unit 201 acquires measurement data measured by the substrate processing apparatus 120. The measurement data includes a first physical quantity indicating a state within the processing container 10 of the substrate processing apparatus 120, and a second physical quantity indicating a state of the semiconductor wafer W that is processed within the processing container 10.

The first physical quantity is, for example, the furnace temperature. The furnace temperature may be measured by, for example, the temperature sensor 60 installed in the processing container 10. The furnace temperature may be measured in each of a plurality of zones obtained by dividing an inside of the processing container 10 into a plurality of areas.

The measurement data may include time-series data of the furnace temperature. The time-series data of the furnace temperature is data in which furnace temperatures measured at a plurality of measurement points included in a measurement target period of a predetermined time length are arranged in a time-series manner. The measurement points may be set at predetermined time intervals. The time intervals may be set arbitrarily.

The second physical quantity is, for example, the wafer vicinity temperature. In the present embodiment, the wafer vicinity temperature is measured by a probe temperature sensor. The probe temperature sensor is a temperature sensor capable of measuring the temperature in the vicinity of a semiconductor wafer disposed in a substrate holder without contact with the semiconductor wafer. The wafer vicinity temperature may be measured for each of the plurality of zones obtained by dividing the inside of the processing container 10 into a plurality of areas.

The measurement data may include time-series data of the wafer vicinity temperature. The time-series data of the wafer vicinity temperature is data in which wafer vicinity temperatures measured at a plurality of measurement points included in a measurement target period of a predetermined time length are arranged in a time-series manner. The measurement points of the wafer vicinity temperature may be the same as the measurement points of the furnace temperature.

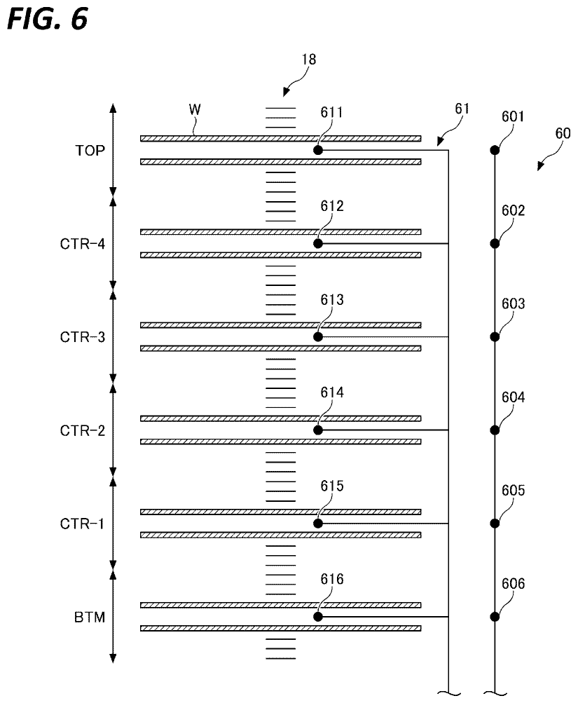

FIG. 6 is a diagram illustrating an example of a temperature sensor. As illustrated in FIG. 6, in the present embodiment, the temperature sensor 60 and a probe temperature sensor 61 are installed in the processing container 10. In the present embodiment, the processing container 10 is divided into six zones BTM, CTR-1 to CTR-4, and TOP from the bottom in a vertical direction upward.

The temperature sensor 60 is provided in the inner tube 11. The temperature sensor 60 includes six temperature measurement portions 601 to 606 disposed one by one in a height direction to correspond to the zones BTM, CTR-1 to CTR-4, and TOP, respectively. The temperature measurement portions 601 to 606 may be arranged in a height range corresponding to each of the zones BTM, CTR-1 to CTR-4, and TOP. For example, each of the temperature measurement portions 601 to 606 may be disposed in the vicinity of the top of each zone, in the vicinity of the center of each zone, or in the vicinity of the bottom of each zone.

The probe temperature sensor 61 is installed in the vicinity of the wafer boat 18. The probe temperature sensor 61 includes six temperature measurement portions 611 to 616 disposed in the vicinity of the semiconductor wafers W disposed in each of the zones BTM, CTR-1 to CTR-4, and TOP. The temperature measurement portions 611 to 616 are supported by leading edges of six support portions provided in the probe temperature sensor 61. For example, the temperature measurement portions 611 to 616 may be disposed between two semiconductor wafers W belonging to each of the zones BTM, CTR-1 to CTR-4, and TOP. The temperature measurement portions 611 to 616 of the probe temperature sensor 61 may be disposed at the same heights as the temperature measurement portions 601 to 606 of the temperature sensor 60, respectively.

The probe temperature sensor 61 may be protected by, for example, a quartz tube. When protected by the quartz tube, the probe temperature sensor 61 may be prevented from being a generation source of contamination in the processing container 10.

When the probe temperature sensor 61 is installed, the wafer boat 18 may not be rotated. Therefore, measurement may not be performed by the probe temperature sensor 61 during process execution.

FIG. 6 illustrates an example in which the inside of the processing container 10 is divided into the six zones BTM, CTR-1 to CTR-4, and TOP, and the temperature measurement portions of each of the temperature sensor 60 and the probe temperature sensor 61 are disposed one by one in each of the zones BTM, CTR-1 to CTR-4, and TOP. However, the configuration of the temperature sensor 60 and the probe temperature sensor 61 is not limited to such a configuration. The inside of the processing container 10 may be divided into five or less zones or seven or more zones. Two or more temperature measurement portions of each of the temperature sensor 60 and the probe temperature sensor 61 may be arranged in each of the zones. The number of temperature measurement portions disposed in each of the zones BTM, CTR-1 to CTR-4, and TOP may be different in the temperature sensor 60 and the probe temperature sensor 61.

The parameter determination unit 202 determines parameters of a mathematical model representing the relationship between the first physical quantity and the second physical quantity. The parameter determination unit 202 determines the parameters of the mathematical model based on the measurement data acquired by the data acquisition unit 201.

The mathematical model is formalized by Equations 1 to 3.

$$\frac{d x}{d t} ( t ) = {A}_{c} x ( t ) + {B}_{c} u ( t ) , \qquad ( 1 )$$

$$x ( t ) = {[ {x}_{1} ( t ) , ⋯ , {x}_{{N}_{w}} ( t ) ]}^{T} ∈ {ℝ}^{{N}_{w}} , \qquad ( 2 )$$

$$u ( t ) = {[ {u}_{1} ( t ) , ⋯ , {u}_{{N}_{z}} ( t ) ]}^{T} ∈ {ℝ}^{{N}_{z}} \qquad ( 3 )$$

Here, t is time, x(t) is a wafer vicinity temperature at time (t), N_{w} is the number of temperature measurement portions of the probe temperature sensor 61, u(t) is a temperature set value at time (t), Nz is the number of the temperature measurement portions of the temperature sensor 60, and T is the transposition of vector. A_{c} and B_{c} are coefficient matrices and are an example of parameters.

The parameter determination unit 202 identifies the coefficient matrices A_{c} and B_{c} based on the measurement data. For example, the parameter determination unit 202 may identify the coefficient matrices A_{c} and B_{c} by using the method of least squares. For example, the parameter determination unit 202 identifies the coefficient matrices A_{c} and B_{c} that minimize Equation 4.

$$ℒ = {\sum }_{k = 1}^{{N}_{s}} {( {x}_{i} [ k ] - {x}_{i}^{( s i m )} [ k ] )}^{2} \qquad ( 4 )$$

Here, Nₛ is the number of time samples at the time of data measurement, i is a temperature measurement portion number of the probe temperature sensor 61, xᵢ[k] is an actually measured value of the wafer vicinity temperature, and xᵢ^{(sim)}[k] is a calculated value of the wafer vicinity temperature based on the mathematical model.

The model conversion unit 203 converts the mathematical model where the parameters determined by the parameter determination unit 202 have been set. The model conversion unit 203 transforms the equation of the mathematical model to allow optimization calculation. The equation transformation may include discretization and parameter division.

For example, the model conversion unit 203 converts the differential equation illustrated in Equation 1 into difference equations illustrated in Equations 5 and 6, using a matrix exponential function. Accordingly, the model conversion unit 203 may discretize the mathematical model.

$$x [ k + 1 ] = A x [ k ] + Bu [ k ] , \qquad ( 5 )$$

$$A = {e}^{{A}_{c} {T}_{s}} , B = {A}_{c}^{- 1} ( A − I ) {B}_{c} \qquad ( 6 )$$

Here, k is a step number, Tₛ is a time length of a step, and I is a unit matrix. The step is a time interval obtained by dividing an optimization target period of a predetermined time length into a plurality of portions. The temperature set value is determined for each step. The time length of the step may be set arbitrarily. The time length of the step may be the same as or may be different from a time interval of measurement points.

Next, the model conversion unit 203 separates the input for the mathematical model into a set temperature and a temperature change amount (ramp rate). The mathematical model after the input separation is represented by Equations 7 and 8.

$$x [ k + 1 ] = A x [ k ] + B u [ k ] + {B}_{r} r [ k ] , \qquad ( 7 )$$

$$A = {e}^{{A}_{c} {T}_{s}} , B = {A}_{c}^{− 1} ( A − I ) {B}_{c} , {B}_{r} = {A}_{c}^{− 2} ( A − {A}_{c} {T}_{s} − I ) {B}_{c} \qquad ( 8 )$$

Here, k is a step number, x[k] is the wafer vicinity temperature in step k, u[k] is a temperature set value in step k, and r[k] is a ramp rate from step k to step k+1.

The optimization unit 204 optimizes the temperature set value based on the mathematical model converted by the model conversion unit 203. The optimization unit 204 optimizes the temperature set value to minimize the stabilization time required for the wafer vicinity temperature to reach the target temperature. The optimization unit 204 may optimize time-series data of the temperature set value. The time-series data of the temperature set value is data in which temperature set values in each of steps included in the optimization target period of the predetermined time length are arranged in a time-series manner.

The optimization unit 204 may acquire the target temperature. The optimization unit 204 may receive the input of the target temperature, or may read the target temperature stored in advance in the storage device of the optimization device 140. The optimization unit 204 may acquire the target temperature from recipe information stored in the control device 121.

The optimization unit 204 may optimize the temperature set value by solving an optimization problem with constraints. For example, the optimization unit 204 may search for a temperature set value that minimizes a predetermined evaluation function while satisfying a predetermined constraint condition.

The evaluation function may be, for example, a function that calculates the integral of a difference between the wafer vicinity temperature and the target temperature. In accordance with an increase in the stabilization time, the integral of the difference between the wafer vicinity temperature and the target temperature increases. In the meantime, in accordance with a decrease in the integral of the difference between the wafer vicinity temperature and the target temperature, the stabilization time is decreased.

The constraint condition may include a plurality of constraint conditions. In the present embodiment, the constraint condition includes the following three constraint conditions. The first constraint condition is that the temperature set value falls within a predetermined range. The second constraint condition is that a maximum value of the wafer vicinity temperatures is less than or equal to a predetermined threshold value. The third constraint condition is that a difference in the wafer vicinity temperature between each of the zone is less than or equal to a predetermined threshold value. In addition, the third constraint condition means that a difference between the wafer vicinity temperature corresponding to a first zone and the wafer vicinity temperature corresponding to a second zone is less than or equal to a predetermined threshold value, for all of the combinations of two zones among the plurality of zones.

The constraint condition may include the following soft constraint. The soft constraint does not necessarily need to be satisfied, but should be satisfied as much as possible. The soft constraint is to minimize an overshoot amount. The overshoot amount is the sum of differences between the wafer vicinity temperatures and the target temperature in a range where the wafer vicinity temperatures exceed the target temperature. By setting the soft constraint, excessive overshoot may be suppressed.

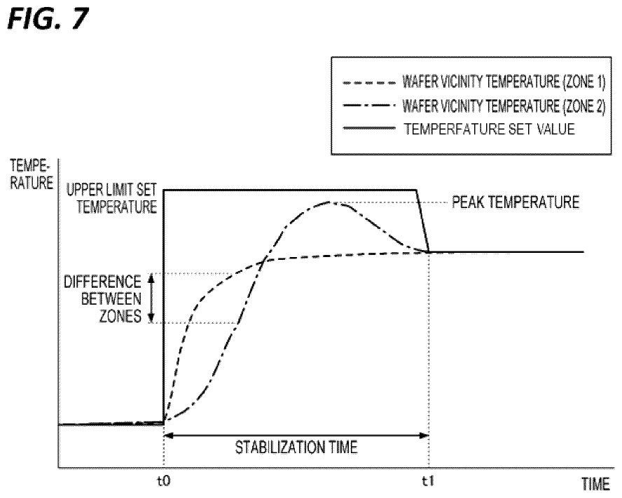

FIG. 7 is a diagram illustrating an example of optimization calculation. As illustrated in FIG. 7, in the optimization calculation, the temperature set value at which the stabilization time is minimized is searched for. The stabilization time is a time interval from time to at which the temperature set value starts to increase to time t1 at which the wafer vicinity temperature in each zone is stabilized.

In the optimization calculation, the temperature set value is searched for in a range where the temperature set value is less than or equal to an upper limit set temperature. Further, in the optimization calculation, the temperature set value is searched for in a range where a peak temperature of the wafer vicinity temperatures in each of the zones is lower than or equal to a predetermined upper limit. The peak temperature is a maximum value of the wafer vicinity temperatures within the stabilization time.

Further, in the optimization calculation, the temperature set value is searched for in a range where a difference between the zones is less than or equal to a predetermined upper limit over the optimization target period. The difference between the zones is a difference between the wafer vicinity temperature of the first zone and the wafer vicinity temperature of the second zone at the same time. In FIG. 7, only a difference between two zones (zone 1 and zone 2) is illustrated, but the temperature set value is searched for such that the difference between the zones is less than or equal to the upper limit for all of the combinations of the zones.

The optimization unit 204 may optimize the time-series data of the temperature set value according to model predictive control (MPC). The model predictive control is an algorithm that optimizes the amount of manipulation of a control target to achieve a purpose while satisfying the constraint condition, based on a predicted value of a control result at each time included in a finite time interval.

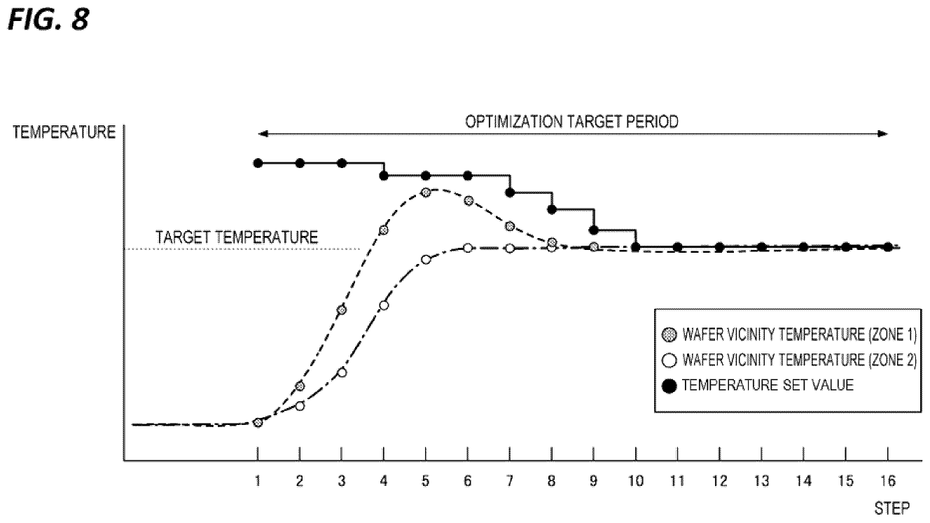

FIG. 8 is a diagram illustrating an example of model predictive control. As illustrated in FIG. 8, in the present embodiment, the optimization target period is divided into N steps (16 steps in FIG. 8). In each step, the temperature set value is calculated such that a predicted value of the wafer vicinity temperature reaches the target temperature in the shortest time while satisfying the constraint condition.

The optimization calculation performed by the optimization unit 204 will be described in more detail. The optimization problem may be formalized by Equations 9 to 12.

$${J}_{1} = {min}_{{u}_{i} ( 1 ) , … , {u}_{i} ( N )} {\sum }_{k = 1}^{N} \vert {x}_{f} − {x}_{i} [ k ] \vert \qquad ( 9 )$$

$$s . t . {u}_{min} \leq {u}_{j} [ k ] \leq {u}_{max} , \qquad ( 10 )$$

$$x \text{?} [ k ] \leq {x}_{max} , \qquad ( 11 )$$

$$− {d}_{max} \leq x \text{?} [ k ] − {x}_{m} [ k ] \leq {d}_{max} \qquad ( 12 )$$

$$\text{?} \text{indicates text missing or illegible when filed}$$

Here, N is the number of steps, x_{f} is a target temperature, uₘᵢₙ is a lower limit of the temperature set value, uₘₐₓ is an upper limit of the temperature set value, xₘₐₓ is an upper limit of the peak temperature, and dₘₐₓ is an upper limit of differences between zones.

The soft constraint may be formalized by Equations 13 to 15.

$${J}_{2} = {\sum }_{k = 1}^{N} c [ k ] , \qquad ( 13 )$$

$$s . t . x [ k ] − {x}_{f} \leq c [ k ] , \qquad ( 14 )$$

$$0 \leq c [ k ] \qquad ( 15 )$$

Here, c[k]∈R^{Nw} is an overshoot amount, and x_{f} is a target temperature.

By organizing Equations 9 to 15, the optimization problem may be formalized by Equations 16 to 25. The optimization problem represented by Equations 16 to 25 may be solved by linear programming, for example, through converting the optimization problem into a linear inequation.

$$minimize J = {J}_{1} + λ {J}_{2} = {\sum }_{k = 1}^{N} {‖ {x}_{f} - x [ k ] ‖}_{∞} + λ c [ k ] \qquad ( 16 )$$

$$subject to x [ k + 1 ] = A x [ k ] + B u [ k ] + {B}_{r} r [ k ] , \qquad ( 17 )$$

$${u}_{m in} \leq u [ k ] \leq {u}_{max} , \qquad ( 18 )$$

$${u}_{min} \leq u [ k ] + {T}_{s} \cdot r [ k ] \leq {u}_{max} , \qquad ( 19 )$$

$$x [ k ] \leq {x}_{max} , \qquad ( 20 )$$

$$- {d}_{max} \leq {x}_{l} [ k ] - {x}_{m} [ k ] \leq {d}_{max} ( l , m = 1 , … , {N}_{w} ) , \qquad ( 21 )$$

$$x [ k ] - {x}_{f} \leq c [ k ] , \qquad ( 22 )$$

$$0 \leq c [ k ] , \qquad ( 23 )$$

$$r [ k ] = r [ k - 1 ] ( {T}_{c} ( p ) \leq k \leq {T}_{c} ( p + 1 ) - 1 ) , \qquad ( 24 )$$

$$u [ k ] = u [ k - 1 ] + {T}_{s} \cdot r [ k - 1 ] ( {T}_{c} ( p ) \leq k \leq {T}_{c} ( p + 1 ) - 1 ) \qquad ( 25 )$$

Here, λ∈R is a hyperparameter, p is the number of recipe steps, and T_{c} is the time of the recipe step.

Equation 16 is an evaluation function, and Equations 17 to 25 are constraint conditions. Equations 18 and 19 are a first constraint condition regarding the range of temperature set values. Equation 20 is a second constraint condition regarding the peak temperature of the wafer vicinity temperature. Equation 21 is a third constraint condition regarding the difference in the wafer vicinity temperature between the zones. Equations 22 and 23 are soft constraints regarding the overshoot amount. Equations 24 and 25 are constraints regarding the temperature set value and the ramp rate for each recipe step.

The result output unit 205 outputs an optimization result obtained by the optimization unit 204. The optimization result includes temperature set values optimized by the optimization unit 204. The optimization result may include time-series data of the optimized temperature set values.

The substrate processing apparatus 120 may perform temperature control within the processing container 10 based on the temperature set value output by the result output unit 205. For example, the control device 121 of the substrate processing apparatus 120 controls the output of the first heater 42 and the second heater 81 such that the furnace temperature becomes the temperature set value. The substrate processing apparatus 120 may measure the furnace temperature and the wafer vicinity temperature while controlling the furnace temperature based on the temperature set value.

The verification unit 206 verifies the optimization result obtained by the optimization unit 204. The verification unit 206 may verify the optimization result based on verification data measured by the substrate processing apparatus 120. The verification data includes the furnace temperature and the wafer vicinity temperature measured by the substrate processing apparatus 120 when the temperature control is performed based on the optimized temperature set value.

The verification unit 206 may determine whether the verification data satisfies a predetermined condition. When the verification data satisfies the predetermined condition, the verification unit 206 may determine that the verification has been successful. Meanwhile, when the verification data does not satisfy the predetermined condition, the verification unit 206 may determine that the verification was failed.

The predetermined condition may include a condition in which, for example, the stabilization time indicated in the verification data satisfies a target value. The target value may be determined based on conventional stabilization time. For example, the target value may be the time sufficiently shorter than the conventional stabilization time. The predetermined condition may include a condition in which, for example, the furnace temperature and the wafer vicinity temperature indicated in the verification data satisfy all of constraint conditions used in the optimization calculation.

When the verification of the optimization result is successful, the verification unit 206 outputs a notification indicating that the verification of the optimization result is successful. The verification unit 206 may output a temperature set value that was successfully verified, together with the notification. When the verification of the optimization result is failed, the verification unit 206 notifies the parameter determination unit 202 that the verification of the optimization result is failed. The parameter determination unit 202 re-determines the parameters of the mathematical model based on the verification data according to the notification indicating that the verification of the optimization result was failed.

The substrate processing apparatus 120 may execute a process on a semiconductor wafer disposed in the processing container 10 based on the temperature set value output by the verification unit 206. Since the temperature set value output by the verification unit 206 is an optimal temperature set value that minimizes the stabilization time, the substrate processing apparatus 120 may process the semiconductor wafer in a short period of time. As a result, the throughput of the substrate processing apparatus 120 is improved, thereby improving productivity.

### <Processing Sequence>

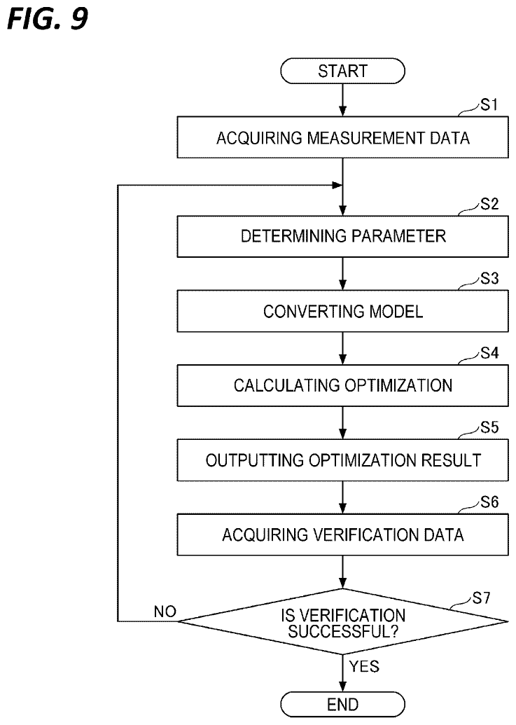

An optimization method executed by the substrate processing system 100 in the present embodiment will be described with reference to FIG. 9. FIG. 9 is a flowchart illustrating an example of the optimization method.

In step S1, the control device 121 of the substrate processing apparatus 120 performs temperature control in the processing container 10. The temperature control includes at least one of a time period for increasing the furnace temperature or a time period for decreasing the furnace temperature. In this case, the probe temperature sensor 61 is installed in the processing container 10. The control device 121 outputs measurement data including the furnace temperature measured by the temperature sensor 60 and the wafer vicinity temperature measured by the probe temperature sensor 61.

The data acquisition unit 201 of the optimization device 140 acquires the measurement data output from the control device 121. Then, the data acquisition unit 201 sends the acquired measurement data to the parameter determination unit 202.

In step S2, the parameter determination unit 202 of the optimization device 140 receives the measurement data from the data acquisition unit 201. Next, the parameter determination unit 202 determines the parameters of a mathematical model representing the relationship between the furnace temperature and the wafer vicinity temperature based on the received measurement data. Then, the parameter determination unit 202 sends the determined parameters to the model conversion unit 203.

In step S3, the model conversion unit 203 of the optimization device 140 receives the parameters of the mathematical model from the parameter determination unit 202. Next, the model conversion unit 203 sets the received parameters in the mathematical model. Then, the model conversion unit 203 converts the mathematical model with the set parameters such that optimization calculation is allowed. Then, the model conversion unit 203 sends the converted mathematical model to the optimization unit 204.

In step S4, the optimization unit 204 of the optimization device 140 receives the converted mathematical model from the model conversion unit 203. In addition, the optimization unit 204 acquires a target temperature. Next, the optimization unit 204 optimizes a temperature set value to minimize the stabilization time required for the wafer vicinity temperature to reach the target temperature, based on the received mathematical model. Then, the optimization unit 204 sends the optimized temperature set value to the result output unit 205.

In step S5, the result output unit 205 of the optimization device 140 receives the optimized temperature set value from the optimization unit 204. Next, the result output unit 205 outputs the optimization result obtained by the optimization unit 204. The optimization result includes the temperature set value optimized by the optimization unit 204.

In step S6, the control device 121 of the substrate processing apparatus 120 performs temperature control within the processing container 10 based on the temperature set value output from the optimization device 140 in step S5. In this case, the probe temperature sensor 61 is installed in the processing container 10. The control device 121 outputs verification data including the furnace temperature measured by the temperature sensor 60 and the wafer vicinity temperature measured by the probe temperature sensor 61. The verification unit 206 of the optimization device 140 acquires the verification data output from the control device 121.

In step S7, the verification unit 206 of the optimization device 140 verifies the optimization result, based on the verification data acquired in step S6. When the verification of the optimization result is successful (YES), the verification unit 206 outputs a notification indicating that the verification of the optimization result is successful, and terminates the processing of the optimization method. Meanwhile, when the verification of the optimization result is failed (NO), the verification unit 206 notifies the parameter determination unit 202 that the verification of the optimization result is successful, and returns the processing to step S2.

After returning to step S2, the parameter determination unit 202 determines the parameters of the mathematical model based on the verification data acquired in step S6. Then, the optimization device 140 re-executes processing steps from step S3 to step S7. In this manner, the optimization device 140 repeatedly executes the optimization of the temperature set value until the verification is successful in step S7.

When the processing of the optimization method is completed, the substrate processing apparatus 120 stores the temperature set values optimized by the optimization device 140. The substrate processing apparatus 120 executes a process on the semiconductor wafer disposed in the processing container 10 based on the temperature set values indicated in the optimization result.

### <Optimization Result>

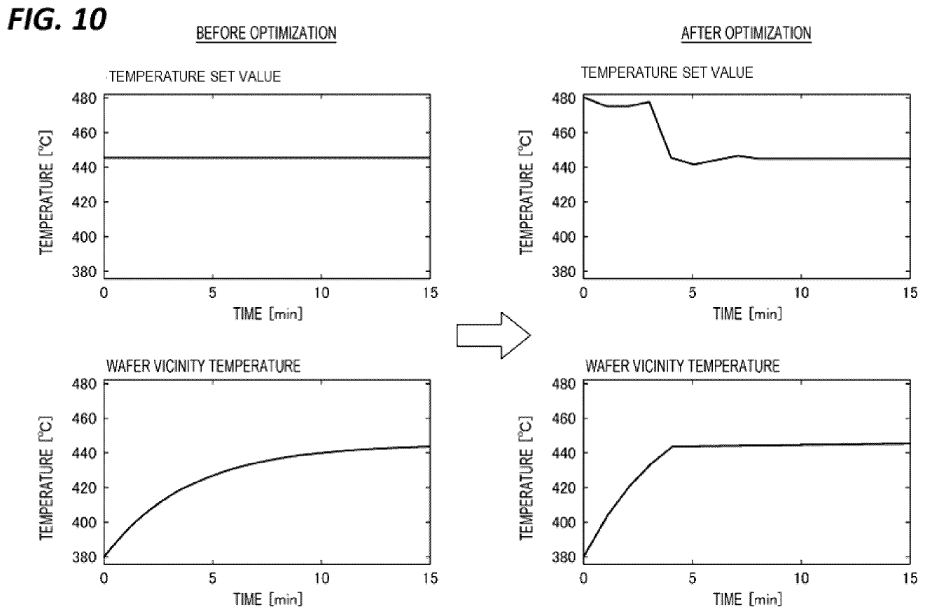

The optimization result according to the present embodiment will be described with reference to FIG. 10. FIG. 10 illustrates an example of an optimization result.

The optimization result illustrated in FIG. 10 is an example of an optimization result targeting temperature control for increasing the furnace temperature to a temperature of 380° C. to 445° C. FIG. 10 illustrates the temperature set value and the wafer vicinity temperature before optimization, and the temperature set value and the wafer vicinity temperature after optimization.

As illustrated in FIG. 10, in the temperature set value after optimization, an overshoot has been performed immediately after the temperature has started to increase, so that the wafer vicinity temperature after optimization has rapidly increased compared to before optimization. As a result, it may be confirmed that the wafer vicinity temperature after optimization is stabilized to the target temperature in a short period of time compared to the wafer vicinity temperature before optimization.

### <Evaluation Results>

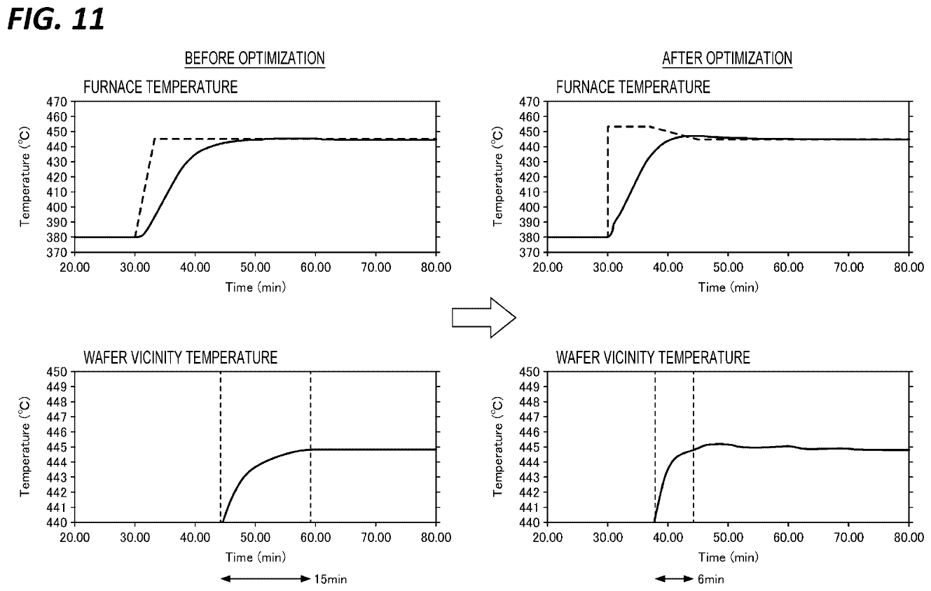

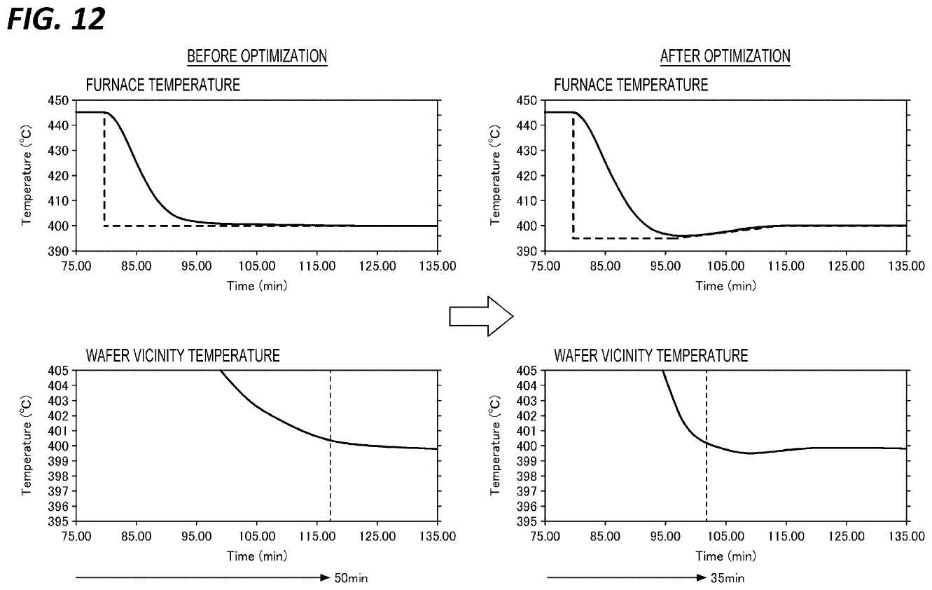

The results of evaluating the optimization result according to the present embodiment will be described with reference to FIGS. 11 and 12.

FIG. 11 illustrates an example of an evaluation result at the time of temperature increase. The evaluation result illustrated in FIG. 11 is an example of an evaluation result targeting temperature control for increasing the furnace temperature to a temperature of 380° C. to 445° C. FIG. 11 illustrates the temperature set value and the wafer vicinity temperature before optimization, and the temperature set value and the wafer vicinity temperature after optimization.

As illustrated in FIG. 11, in the temperature set value before optimization, it was required to take about 15 minutes for the wafer vicinity temperature to reach a target temperature. Meanwhile, in the temperature set value after optimization, it took about 6 minutes for the wafer vicinity temperature to reach the target temperature. Therefore, in the temperature control for increasing the furnace temperature, the stabilization time could be shortened by about 9 minutes by optimizing the temperature set value.

FIG. 12 illustrates an example of an evaluation result at the time of temperature decrease. The evaluation result illustrated in FIG. 12 is an example of the evaluation result targeting temperature control for decreasing the furnace temperature to a temperature of 445° C. to 400° C. FIG. 12 illustrates the temperature set value and the wafer vicinity temperature before optimization, and the temperature set value and the wafer vicinity temperature after optimization.

As illustrated in FIG. 12, in the temperature set value before optimization, it was required to take about 50 minutes for the wafer vicinity temperature to reach a target temperature. Meanwhile, in the temperature set value after optimization, it took about 35 minutes for the wafer vicinity temperature to reach the target temperature. Therefore, in the temperature control for decreasing the furnace temperature, the stabilization time could be shortened by about 15 minutes by optimizing the temperature set value.

In FIG. 11 and FIG. 12, it was illustrated that the time required for the wafer surface temperature to reach the target temperature may be shortened compared to a conventional case, by using the temperature set value optimized according to the present embodiment.

### Effect of Embodiments

The optimization device 140 in the present embodiment determines parameters of a model representing the relationship between a first physical quantity and a second physical quantity based on measurement data acquired by measuring the first physical quantity indicating a state within a processing container for processing a processing target and a second physical quantity indicating a state of the processing target, and optimizes a set value of the first physical quantity to minimize the time required for the second physical quantity to satisfy a target value, based on a model with the parameters set therein.

In one aspect, according to the present embodiment, the state of the processing target may be controlled with high accuracy. In another aspect, according to the present embodiment, since it is unnecessary to change a hardware design of the substrate processing apparatus, the cost required to improve the accuracy of temperature control may be reduced.

The first physical quantity may include the temperature within the processing container, and the second physical quantity may include the surface temperature of the processing target. In one aspect, according to the present embodiment, the temperature within the processing container may be appropriately set in consideration of a response difference between the temperature within the processing container and the surface temperature of the processing target. In another aspect, according to the present embodiment, since the temperature within the processing container is appropriately set, the surface temperature of the processing target is stabilized in a short period of time.

The measurement data may include time-series data of the first physical quantity and time-series data of the second physical quantity. The optimization device 140 may optimize the time-series data of the set values of the first physical quantity. According to the present embodiment, the temperature within the processing container may be appropriately set according to the model predictive control.

The optimization device 140 may search for a set value of the first physical quantity that satisfies a predetermined constraint condition. The constraint condition may include a condition in which the set value of the first physical quantity falls within a predetermined range. The constraint condition may include a condition in which a maximum value of the second physical quantity is less than or equal to a predetermined threshold value. The constraint condition may include a condition in which a difference between a first second physical quantity corresponding to a first area within the processing container and a second second physical quantity corresponding to a second area different from the first area is less than or equal to a predetermined threshold value. According to the present embodiment, since the set value of the first physical quantity satisfies the constraint condition, the state of the processing target may be appropriately controlled.

The optimization device 140 may optimize the set value of the first physical quantity such that the sum of values obtained by subtracting the target value from the second physical quantity is further minimized. According to the present embodiment, since the overshoot amount is suppressed, the state of the processing target may be appropriately controlled.

### OTHER EMBODIMENTS

The substrate processing apparatus for executing a process including a substrate processing method of the present disclosure is not limited to a heat treatment apparatus. The substrate processing apparatus may be applied to any type of apparatuses, such as an atomic layer deposition (ALD) apparatus, a capacitively-coupled plasma (CCP) apparatus, an inductively-coupled plasma (ICP) apparatus, a radial line slot antenna (RLSA) apparatus, an electron cyclotron resonance plasma (ECR) apparatus, and a helicon wave plasma (HWP) apparatus.

In addition, the substrate processing apparatus of the present disclosure may be applied to any of an apparatus using plasma and an apparatus without using plasma, as long as the substrate processing apparatus is an apparatus that performs a predetermined processing (e.g., a film formation processing or an etching processing) on a substrate. Furthermore, the substrate processing apparatus of the present disclosure may be applied to any of a single-substrate processing apparatus that processes substrates one by one, a batch apparatus that processes a plurality of substrates at once, and a semi-batch apparatus that processes, at once, a smaller number of substrates than the number of substrates processed at once by the batch apparatus.

In the present embodiment, an example in which the technique of the present disclosure is applied to temperature control in the processing container of the vertical-type heat treatment apparatus has been described, but the technique of the present disclosure may be applied to other substrate processing apparatuses. For example, the technique of the present disclosure may be applied to the temperature control of a stage heater of a single-substrate processing apparatus. In addition, the technique of the present disclosure is not limited to temperature control, and may be applied to, for example, pressure control or gas flow control. For example, the technique of the present disclosure may be applied to any control target, as long as there exists a response difference between a sensor value and an actual physical quantity, and the actual physical quantity of the control target may be measured even temporarily.

In one aspect, the state of the processing target may be controlled with high accuracy.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
acquisition circuitry configured to acquire measurement data including a first physical quantity indicating a state within a processing container for processing a processing target and a second physical quantity indicating a state of the processing target;
determination circuitry configured to determine a parameter of a model representing a relationship between the first physical quantity and the second physical quantity, based on the measurement data; and
optimization circuitry configured to optimize a set value of the first physical quantity to minimize a time required for the second physical quantity to satisfy a target value, based on the model with the parameter determined by the determination circuitry set therein.

2. The information processing apparatus according to claim 1, wherein the measurement data includes time-series data of the first physical quantity and time-series data of the second physical quantity, and
the optimization circuitry are configured to optimize time-series data of the set value.

3. The information processing apparatus according to claim 1, wherein the optimization circuitry are configured to search for a set value of the first physical quantity that satisfies a predetermined constraint condition.

4. The information processing apparatus according to claim 3, wherein the constraint condition includes a condition in which the set value falls within a predetermined range.

5. The information processing apparatus according to claim 3, wherein the constraint condition includes a condition in which a maximum value of the second physical quantity is less than or equal to a predetermined threshold value.

6. The information processing apparatus according to claim 3, wherein the second physical quantity includes a first second physical quantity corresponding to a first area within the processing container, and a second second physical quantity corresponding to a second area different from the first area, and
the constraint condition includes a condition in which a difference between the first second physical quantity and the second second physical quantity is less than or equal to a predetermined threshold value.

7. The information processing apparatus according to claim 3, wherein the optimization circuitry are configured to optimize the set value of the first physical quantity such that a sum of values obtained by subtracting the target value from the second physical quantity is further minimized.

8. The information processing apparatus according to claim 1, wherein the first physical quantity includes a temperature within the processing container, and
the second physical quantity includes a temperature in a vicinity of the processing target.

9. A substrate processing apparatus including a processing container for processing a processing target, the substrate processing apparatus comprising:
acquisition circuitry configured to acquire measurement data including a first physical quantity indicating a state within the processing container and a second physical quantity indicating a state of the processing target;
determination circuitry configured to determine a parameter of a model representing a relationship between the first physical quantity and the second physical quantity, based on the measurement data; and
optimization circuitry configured to optimize a set value of the first physical quantity to minimize a time required for the second physical quantity to satisfy a target value, based on the model with the parameter determined by the determination circuitry set therein; and
control circuitry configured to control a state within the processing container, based on the set value optimized by the optimization circuitry.

10. An information processing method executed by an information processing apparatus, the information processing method comprising:
acquiring measurement data including a first physical quantity indicating a state within a processing container for processing a processing target and a second physical quantity indicating a state of the processing target;
determining a parameter of a model representing a relationship between the first physical quantity and the second physical quantity, based on the measurement data; and
optimizing a set value of the first physical quantity to minimize a time required for the second physical quantity to satisfy a target value, based on the model with the parameter determined by the determination circuitry set therein.
